(19) United States
(12) Patent Application Publication
(10) Pub. No.: US 2024/0272550 A1
(43) Pub. Date: Aug. 15, 2024

(54) RESIST COMPOSITION AND PATTERN FORMING PROCESS

(71) Applicant: Shin-Etsu Chemical Co., Ltd., Tokyo (JP)

(72) Inventors: Masaki Ohashi, Joetsu-shi (JP); Seiichiro Tachibana, Joetsu-shi (JP); Shun Kikuchi, Joetsu-shi (JP); Ryunosuke Handa, Joetsu-shi (JP)

(73) Assignee: Shin-Etsu Chemical Co., Ltd., Tokyo (JP)

(21) Appl. No.: 18/539,887

(22) Filed: Dec. 14, 2023

(30) Foreign Application Priority Data
Dec. 26, 2022 (JP) 2022-208497

(51) Int. Cl. G03F 7/029; G03F 7/004; G03F 7/039; G03F 7/32

(52) U.S. Cl. CPC G03F 7/0295; G03F 7/0048; G03F 7/039; G03F 7/322

(57) ABSTRACT

A resist composition is provided that comprises a hypervalent iodine compound having the formula (1), a carboxy group-containing polymer, and a solvent. In formula (1), n is an integer of 0 to 5, R¹ and R² are each independently halogen or a C₁-C₁₀ hydrocarbyl group which may contain a heteroatom, R¹ and R² may bond together to form a ring with the carbon atoms to which they are attached and the intervenient atoms. R³ is halogen or a C₁-C₄₀ hydrocarbyl group which may contain a heteroatom.

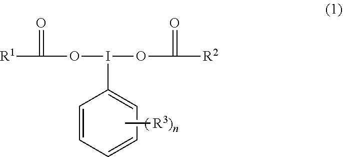

### CROSS-REFERENCE TO RELATED APPLICATIONS

This non-provisional application claims priority under 35 U.S.C. § 119(a) on Patent Application No. 2022-208497 filed in Japan on Dec. 26, 2022, the entire contents of which are hereby incorporated by reference.

### TECHNICAL FIELD

This invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a processing dimension of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. Therefore, it has been proposed to copolymerize a polymer with an acid generator in the form of an onium salt having a polymerizable unsaturated bond. With respect to the patterning of a resist film to a processing dimension of 16 nm et seq., it is believed impossible in the light of acid diffusion to form such a pattern from a chemically amplified resist composition. It would be desirable to have a non-chemically amplified resist composition.

A typical non-chemically amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where processing dimensions become smaller than ever.

Patent Document 2 discloses a negative resist composition comprising a tin compound. Based on tin element having high EUV absorption, this resist composition is improved in stochastics and achieves a high sensitivity and high resolution. Such so called metal resist compositions, however, suffer from many problems including low solubility in resist solvents, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2018-5224
Patent Document 2: JP-A 2021-503482
Non-Patent Document 1: SPIE Vol. 5039 p1 (2003)
Non-Patent Document 2: SPIE Vol. 6520 p65203L-1 (2007)

### SUMMARY OF THE INVENTION

An object of the invention is to provide a non-chemically amplified resist composition which exhibits a high sensitivity and resolution when processed by photolithography using high-energy radiation, typically EB and EUV lithography, and a pattern forming process using the same.

The inventors have found that a resist composition based on a predetermined hypervalent iodine compound and a carboxy group-containing polymer has a very high sensitivity, forms a resist film having a satisfactory resolution, and is thus quite useful in precise micropatterning.

The invention provides a resist composition and a pattern forming process described below.
1. A resist composition comprising a hypervalent iodine compound having the formula (1), a carboxy group-containing polymer, and a solvent:

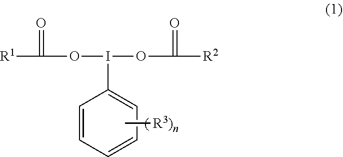

wherein n is an integer of 0 to 5,
R¹ and R² are each independently halogen or a C₁-C₁₀ hydrocarbyl group which may contain a heteroatom, R¹ and R² may bond together to form a ring with the carbon atoms to which they are attached and the intervenient atoms, and
R³ is halogen or a C₁-C₄₀ hydrocarbyl group which may contain a heteroatom.
2. The resist composition of the item 1 wherein the carboxy group-containing polymer contains a recurring unit having the formula (2):

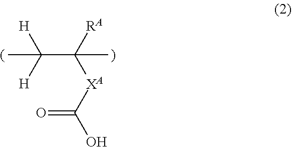

wherein R^{A} is a hydrogen atom, fluorine atom, methyl group, or trifluoromethyl group,
X^{A} is a single bond, phenylene group, naphthylene group, or *—C(═O)—O—X^{A1}— wherein X^{A1} is a C₁-C₁₀ saturated hydrocarbylene group, phenylene group, or naphthylene group, the C₁-C₁₀ saturated hydrocarbylene group may contain a hydroxy group, ether bond, ester bond, or lactone ring, and * designates a valence bond to a carbon atom in a main chain.
3. A pattern forming process comprising the steps of applying the resist composition of the item 1 or 2 onto a substrate to form a resist film thereon, exposing the resist film to an electron beam (EB) or an extreme ultraviolet radiation (EUV), and developing the exposed resist film in a developer.
4. The pattern forming process of the item 3 wherein the developer is an organic solvent.

### Advantageous Effects of the Invention

The resist composition exhibits both high sensitivity and resolution when processed by EB and EUV lithography and is quite useful in micropatterning.

### DETAILED DESCRIPTION OF THE INVENTION

### Resist Composition

One embodiment of the invention is a resist composition based on a predetermined hypervalent iodine compound and a carboxy group-containing polymer.

### Hypervalent Iodine Compound

The hypervalent iodine compound is a three-coordinate hypervalent iodine compound having the formula (1).

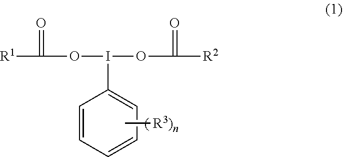

In the formula (1), n is an integer of 0 to 5.

In the formula (1), R¹ and R² are each independently halogen or a C₁-C₁₀ hydrocarbyl group which may contain a heteroatom. R¹ and R² may bond together to form a ring with the carbon atoms to which they are attached and the intervenient atoms. Examples of the halogen include fluorine, chlorine, bromine, and iodine. The C₁-C₁₀ hydrocarbyl group may be saturated or unsaturated, and straight, branched, or cyclic. Examples thereof include C₁-C₁₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₂-C₁₀ alkenyl groups such as vinyl and allyl; C₆-C₁₀ aryl groups such as phenyl and naphthyl; and combinations thereof. Also included are hydrocarbyl groups in which some or all of the hydrogen atoms are substituted by a moiety containing a heteroatom such as oxygen, sulfur, nitrogen, or halogen, and some constituent —CH₂— is replaced by a moiety containing a heteroatom such as oxygen, sulfur, or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ and R² are preferably C₁-C₄ hydrocarbyl groups.

In the formula (1), R³ is halogen or a C₁-C₄₀ hydrocarbyl group which may contain a heteroatom. When n is an integer of 2 to 5, a plurality of R³ may be the same or different. Examples of the halogen include fluorine, chlorine, bromine, and iodine. The C₁-C₄₀ hydrocarbyl group may be saturated or unsaturated, and straight, branched, or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl; and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen, or halogen, and some constituent —CH₂— is replaced by a moiety containing a heteroatom such as oxygen, sulfur, or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

Examples of the hypervalent iodine compound having the formula (1) are shown below, but not limited thereto.

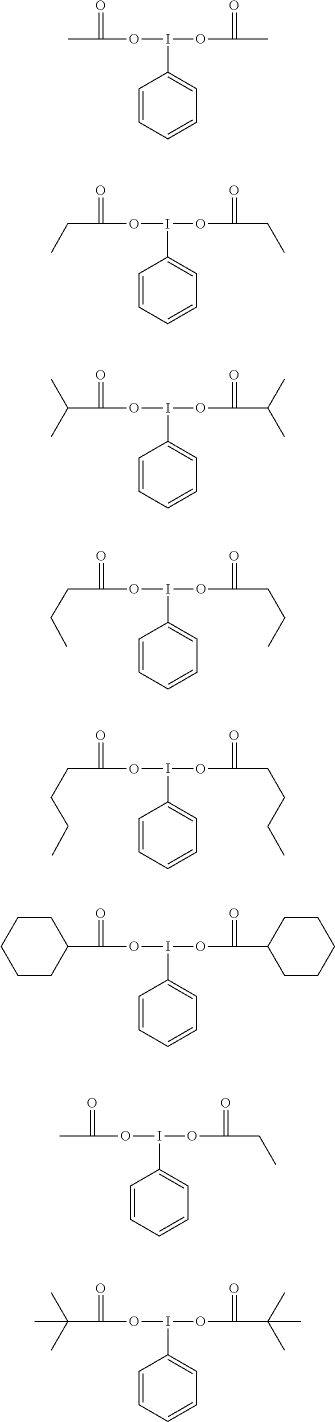

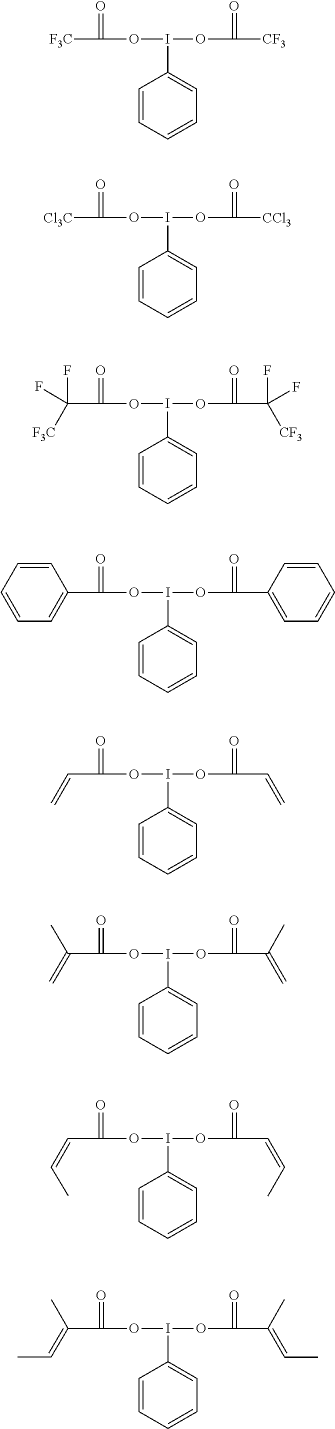

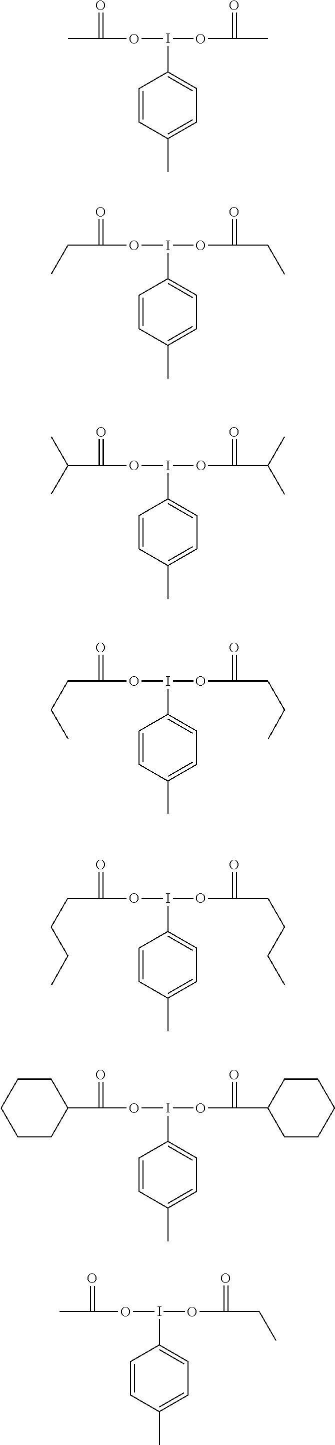

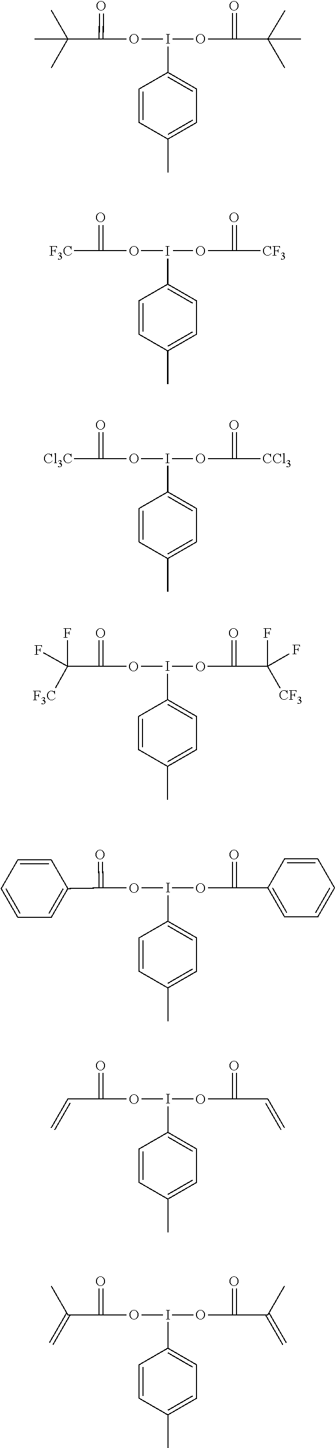

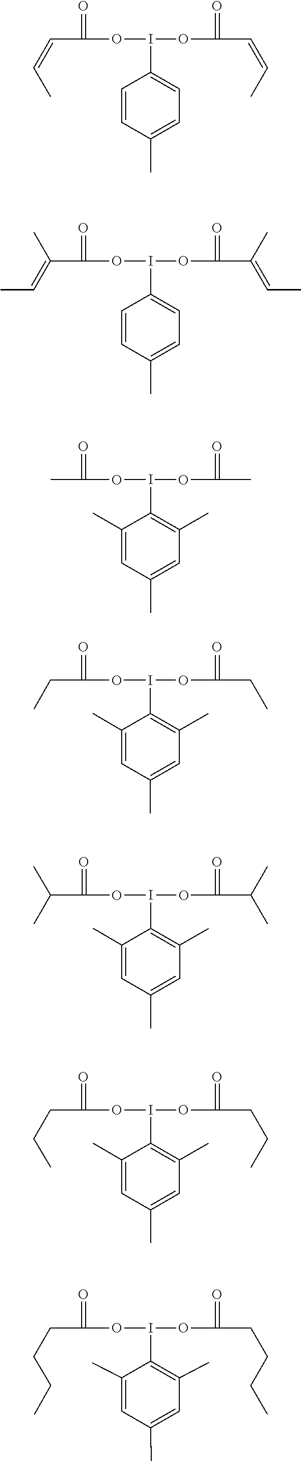

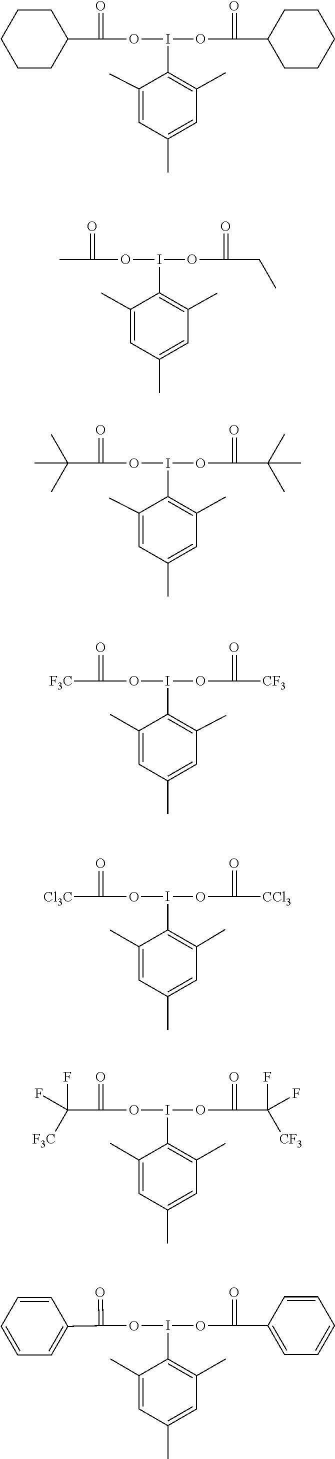

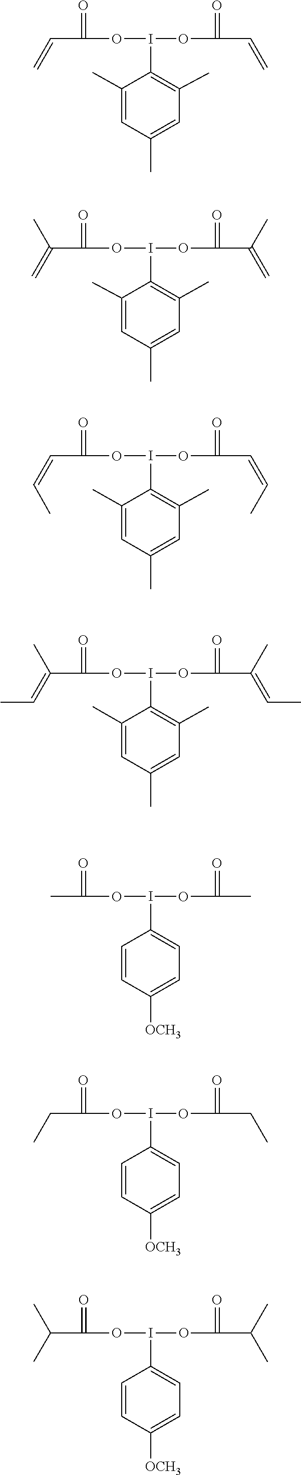

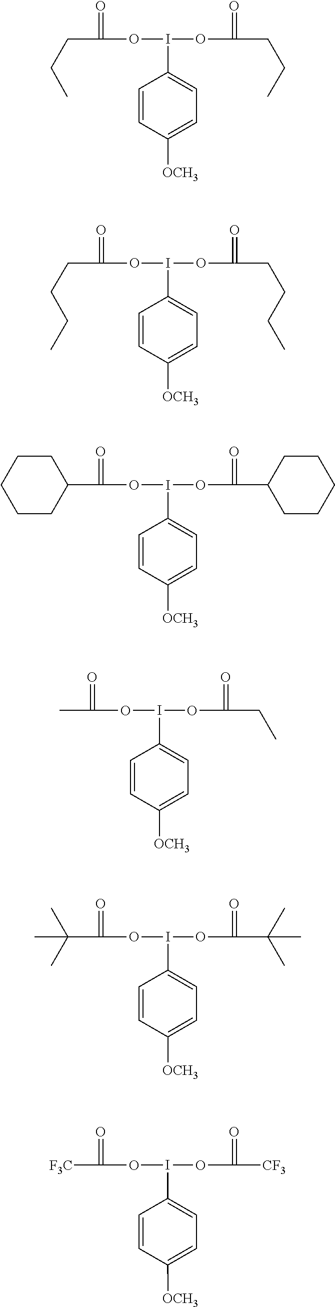

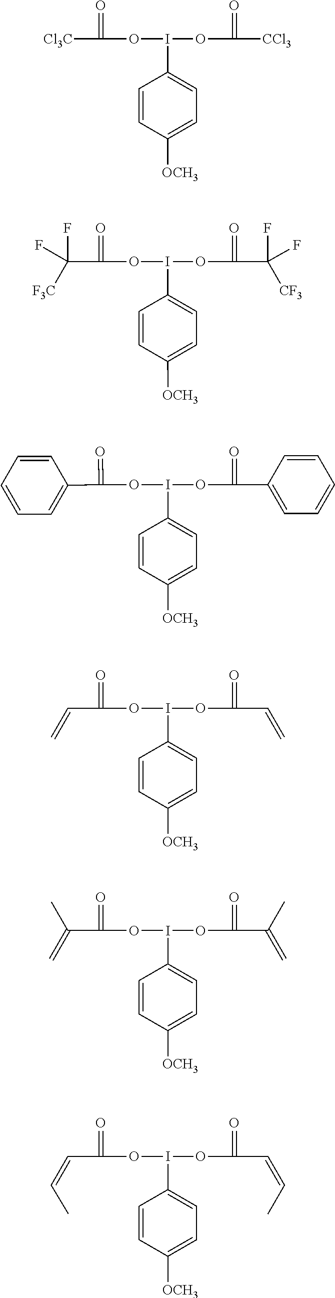

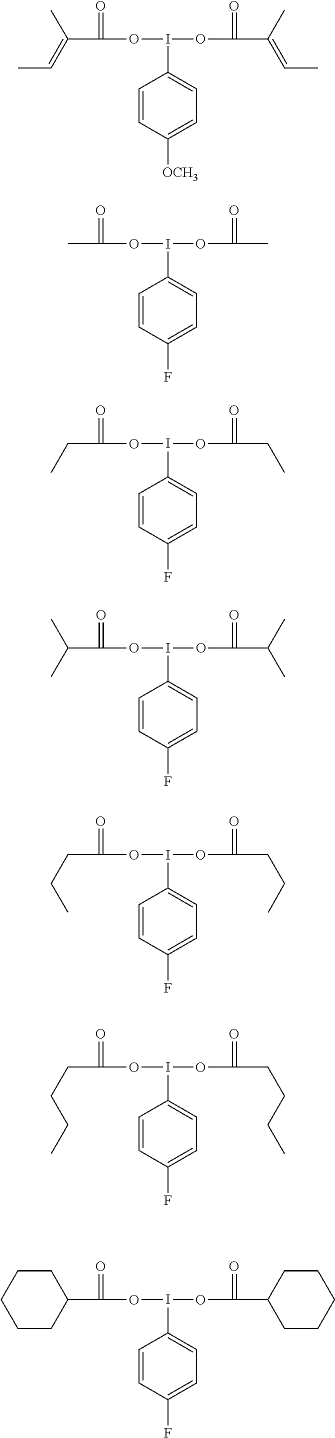

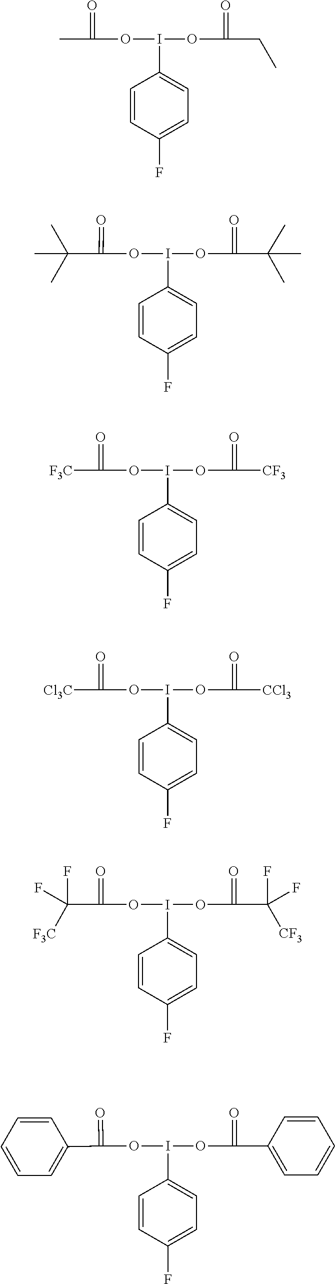

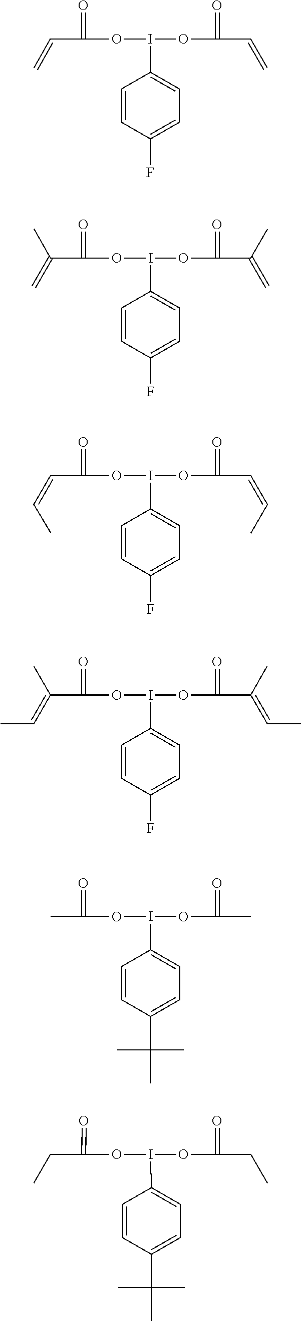

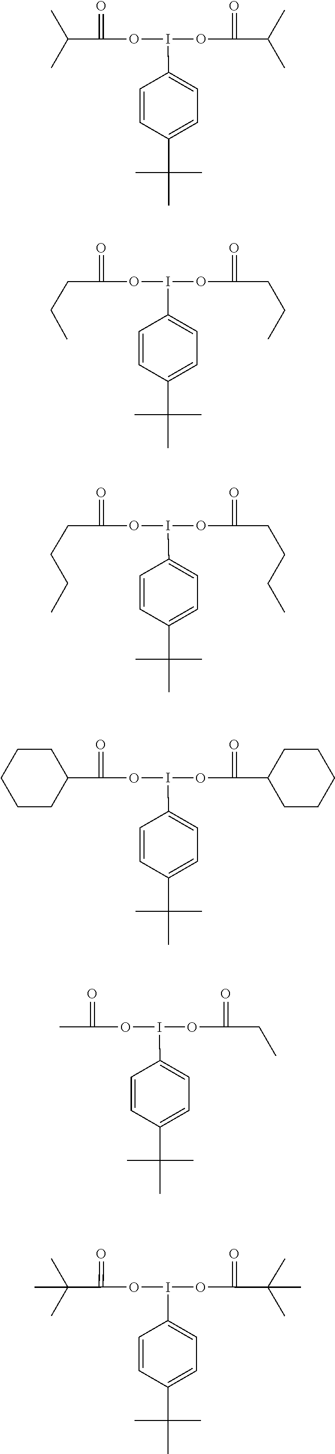

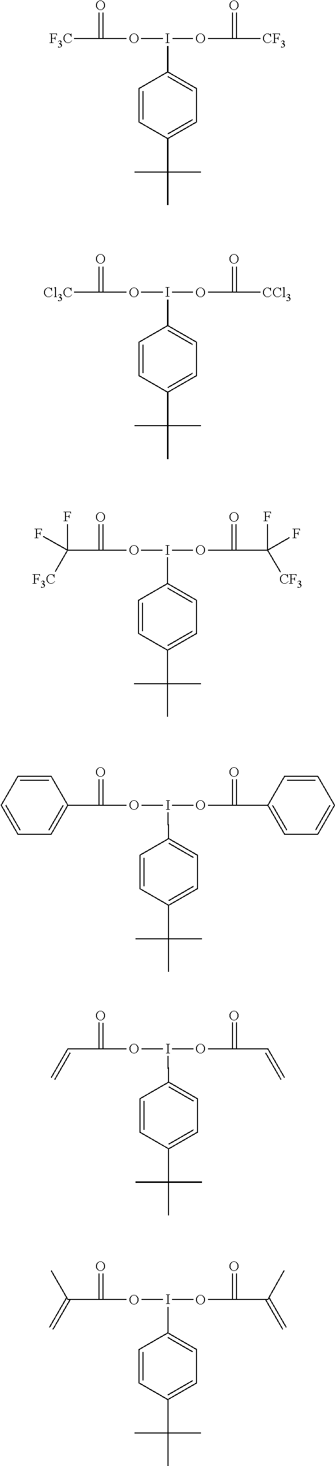

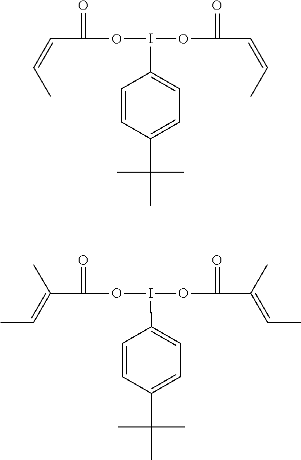 [SMILES: C/C=C\C(=O)OI(OC(=O)/C=C\C)c1ccc(C(C)(C)C)cc1 ; C/C=C(\C)C(=O)OI(OC(=O)/C(C)=C/C)c1ccc(C(C)(C)C)cc1]

### Carboxy Group-Containing Polymer

The carboxy group-containing polymer preferably contains a carboxy group-containing recurring unit. Preferably, the carboxy group-containing recurring unit has the formula (2).

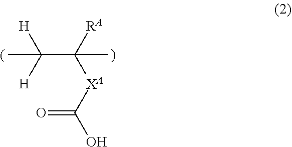

In the formula (2), R^{A} is a hydrogen atom, fluorine atom, methyl group, or trifluoromethyl group. X^{A} is a single bond, phenylene group, naphthylene group, or *—C(═O)—O—X^{A1}—. X^{A1} is a C₁-C₁₀ saturated hydrocarbylene group, phenylene group, or naphthylene group, and the saturated hydrocarbylene group may contain a hydroxy group, ether bond, ester bond, or lactone ring. * designates a valence bond to a carbon atom in a main chain.

Examples of the carboxy group-containing recurring unit are shown below, but not limited thereto. Herein R^{A} is as defined above.

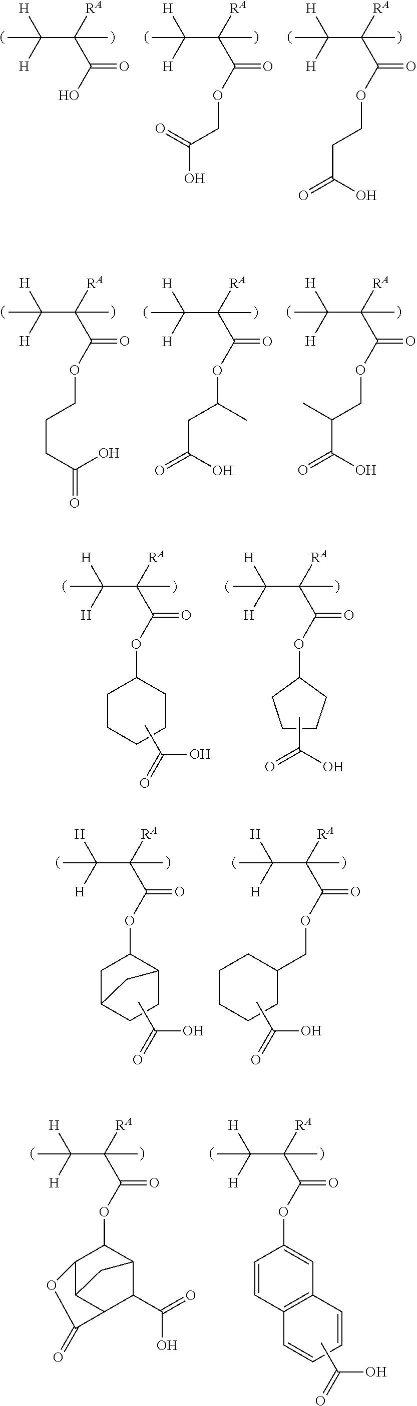

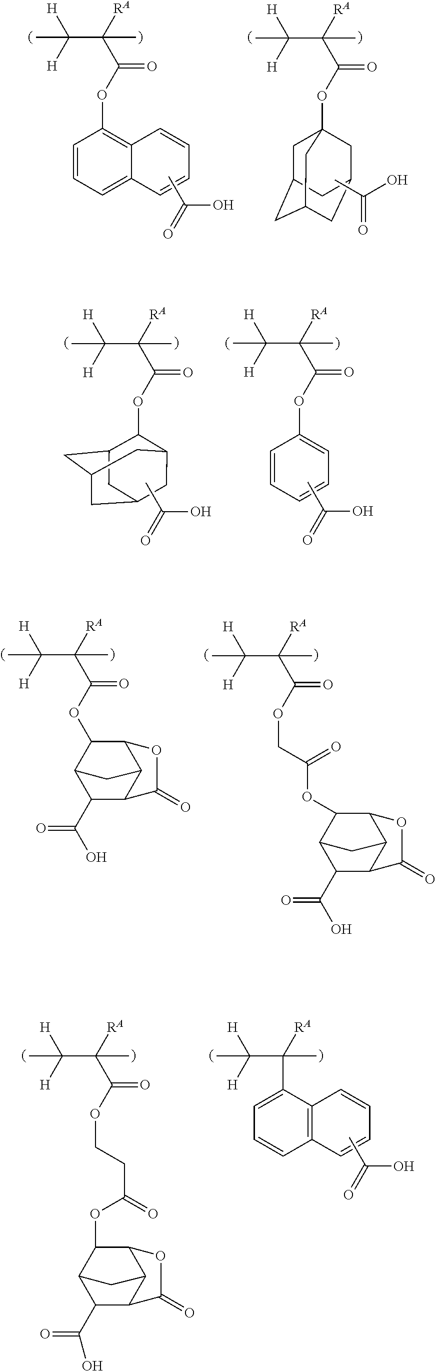

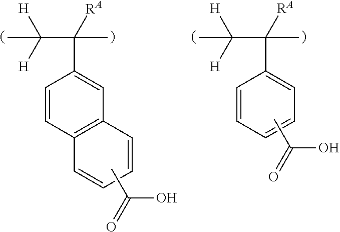

The carboxy group-containing polymer may further contain a recurring unit other than the carboxy group-containing recurring unit (hereinafter, also referred to as another recurring unit). Another recurring unit is not particularly limited, and a recurring unit is preferable that is capable of improving the solubility, in a solvent, of an insoluble polymer containing only a recurring unit having a carboxy group. Another recurring unit preferably has a C₁-C₂₀ hydrocarbyl group which may contain at least one selected from a fluorine atom, a hydroxy group other than a phenolic hydroxy group, a cyano group, a carbonyl group, an ester bond, an ether bond, a sulfide bond, a carbonate bond, a lactone ring, and a sultone ring.

Examples of another recurring unit are shown below, but not limited thereto. Herein R^{A} is as defined above.

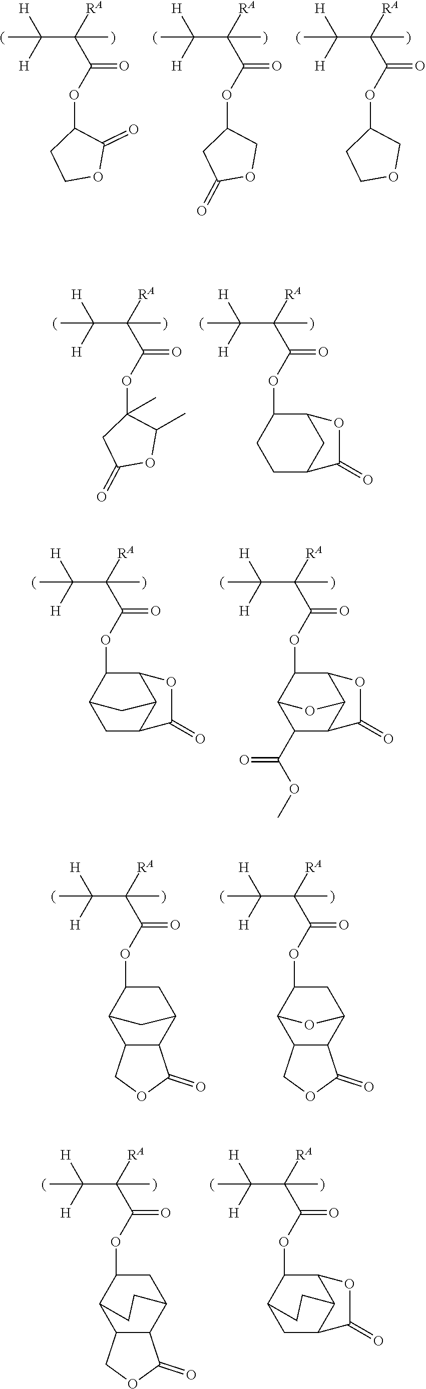

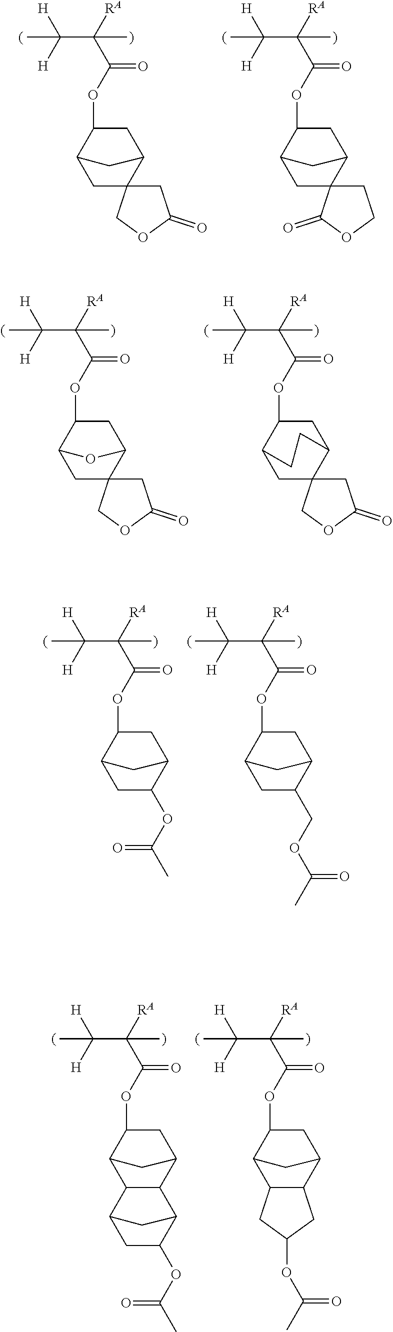

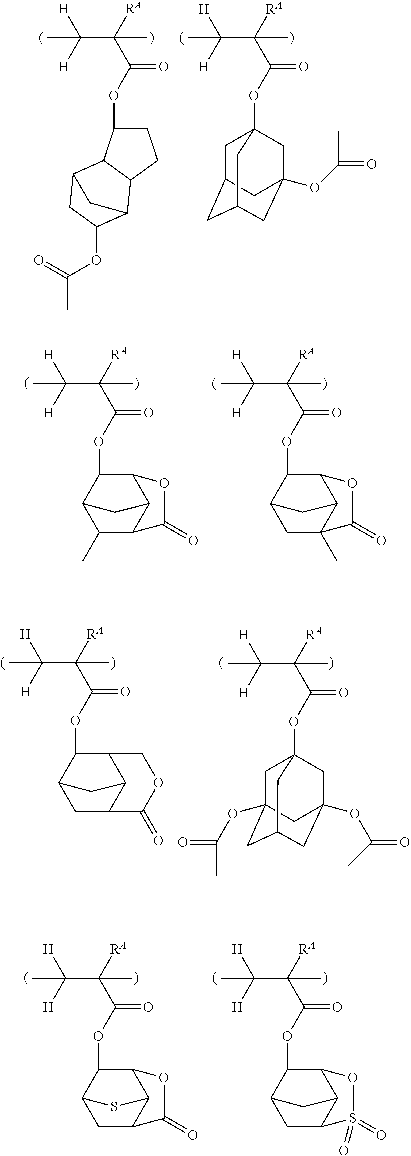

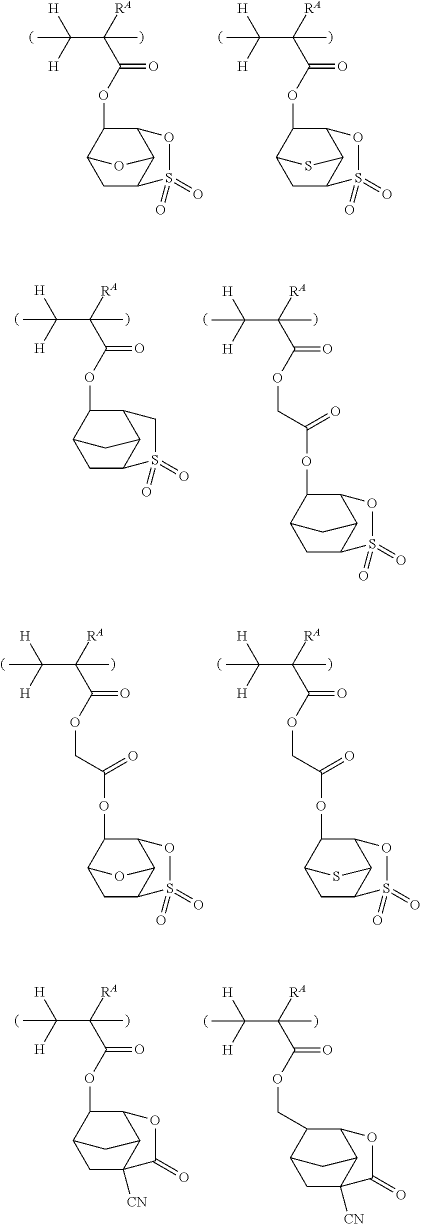

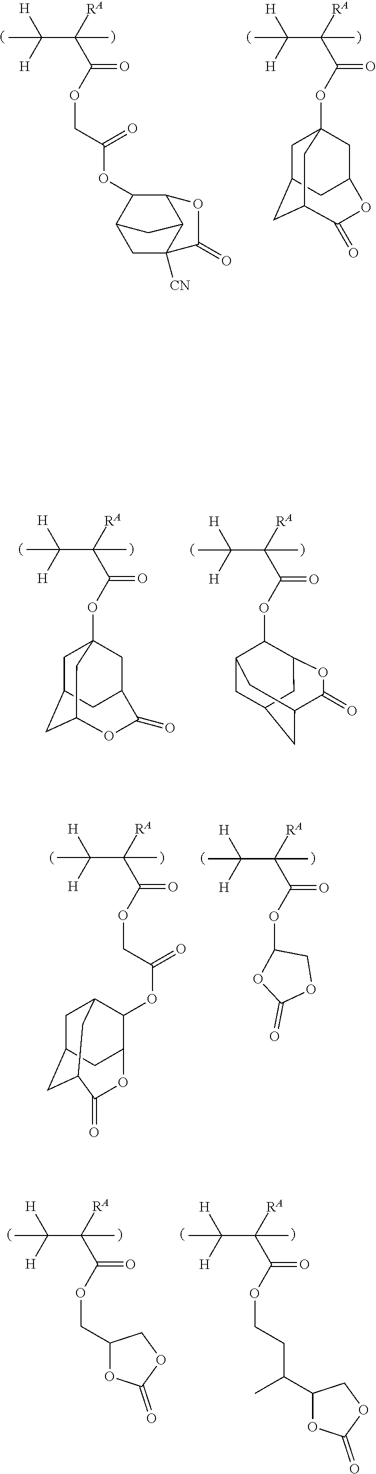

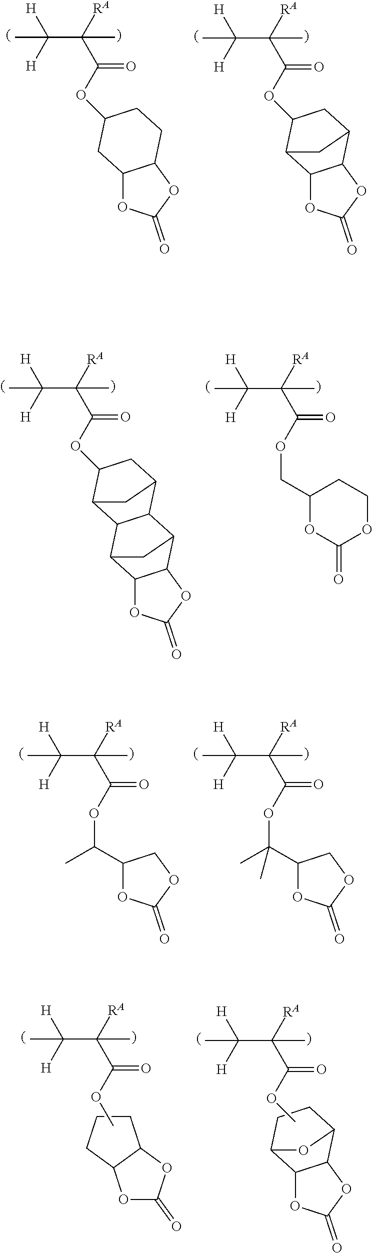

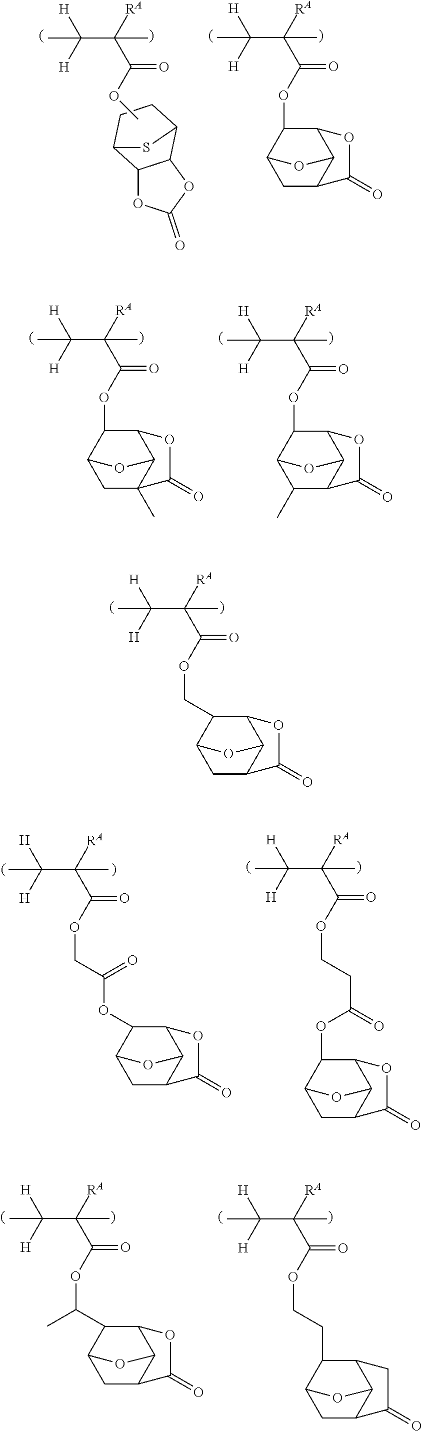

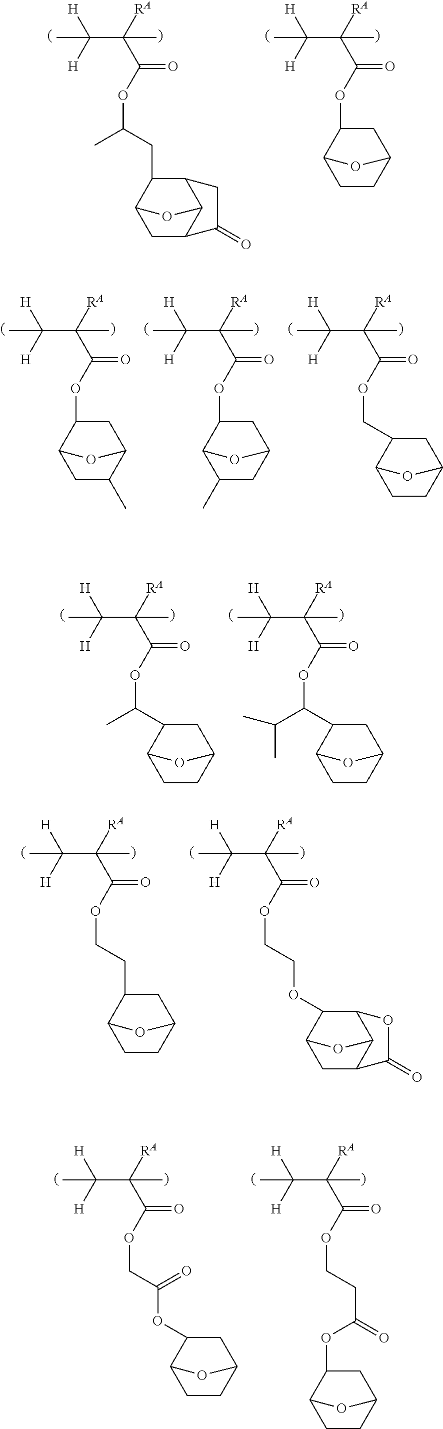

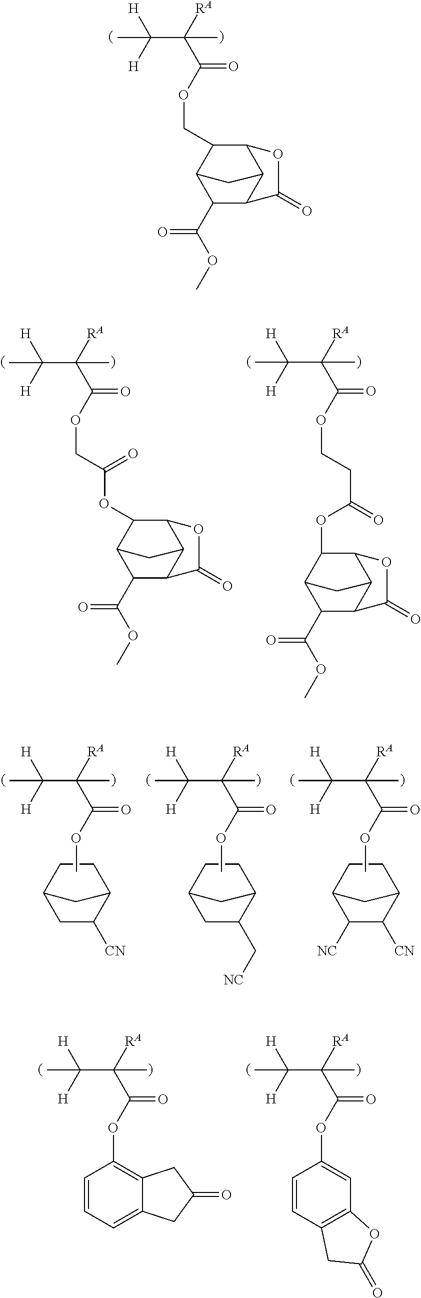

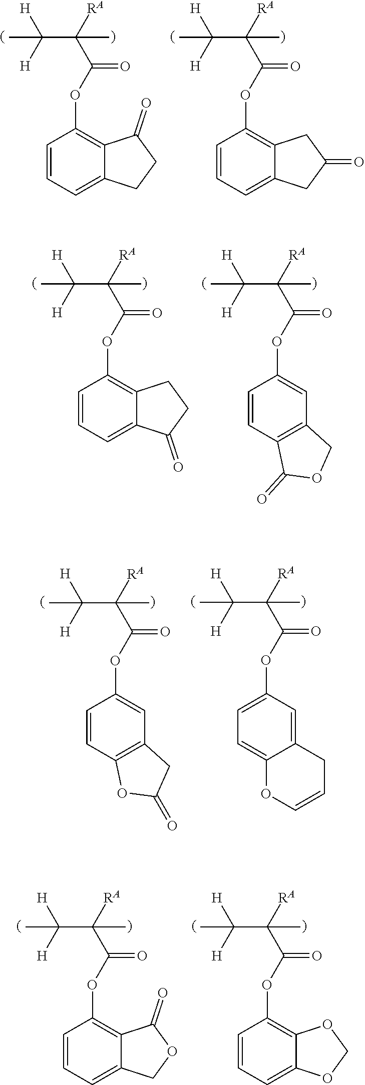

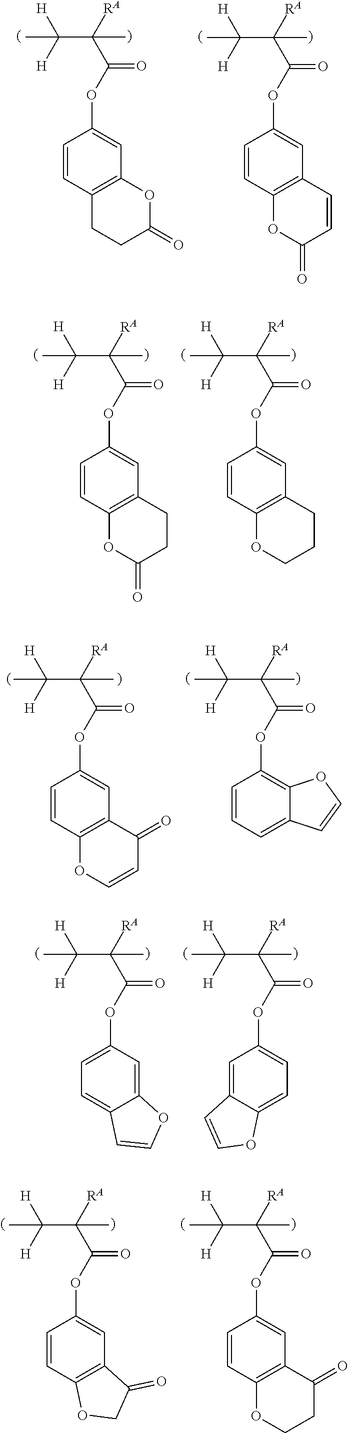

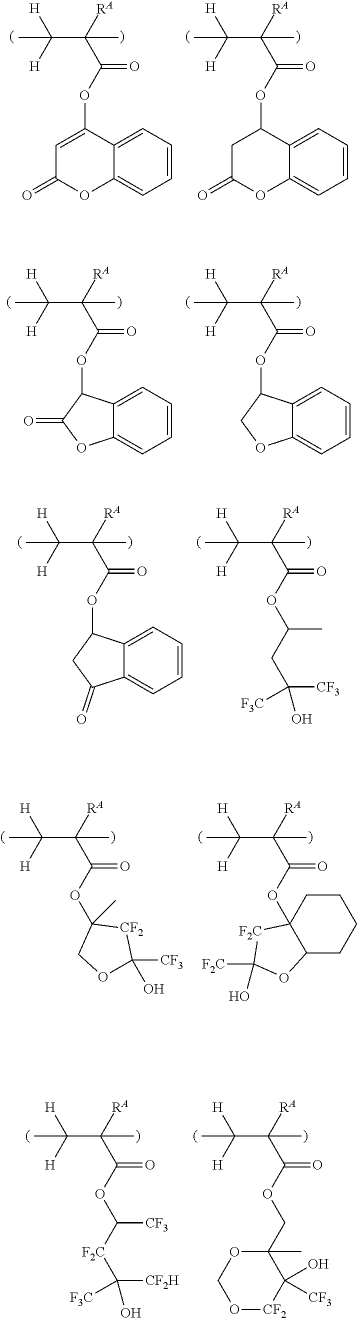

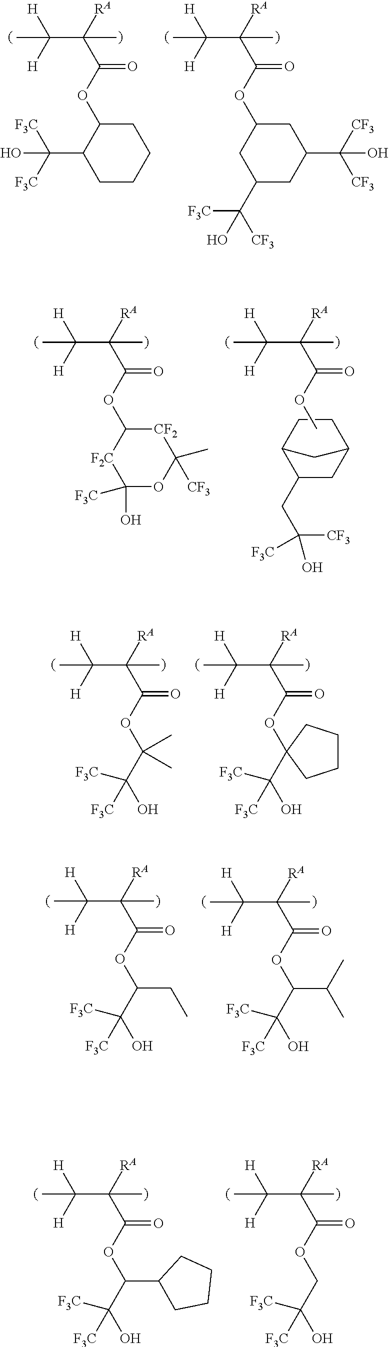

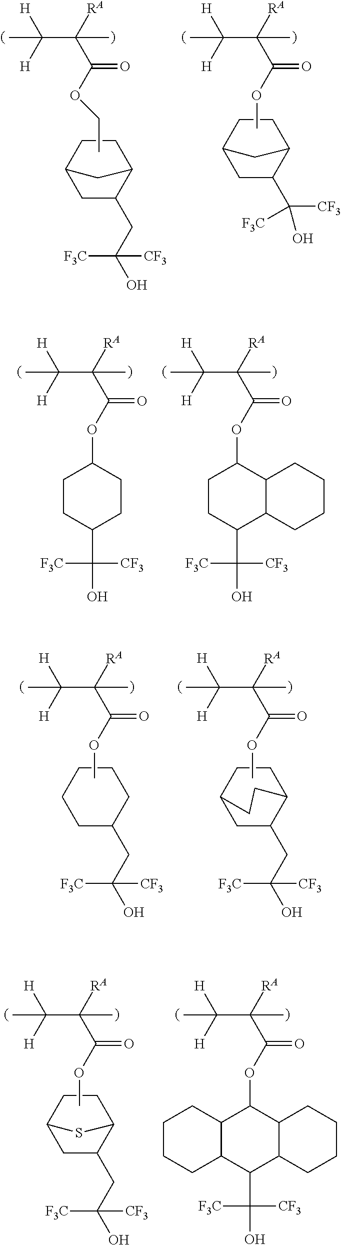

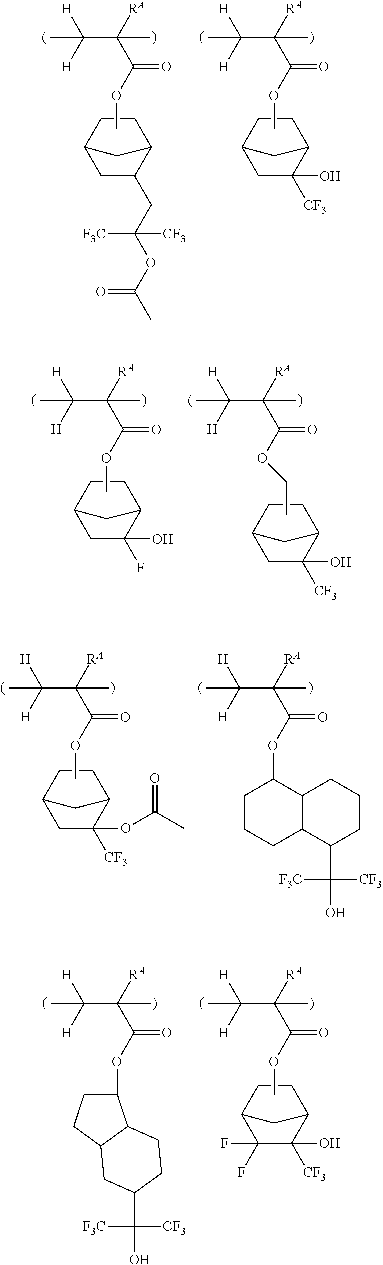

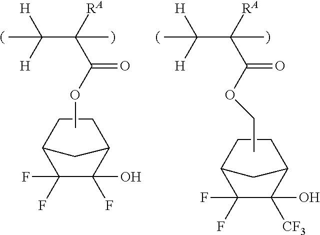

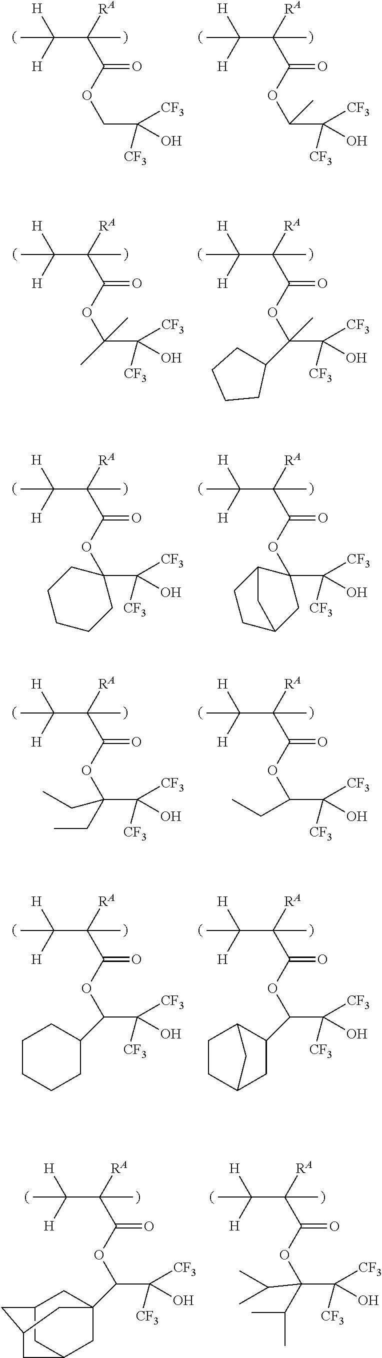

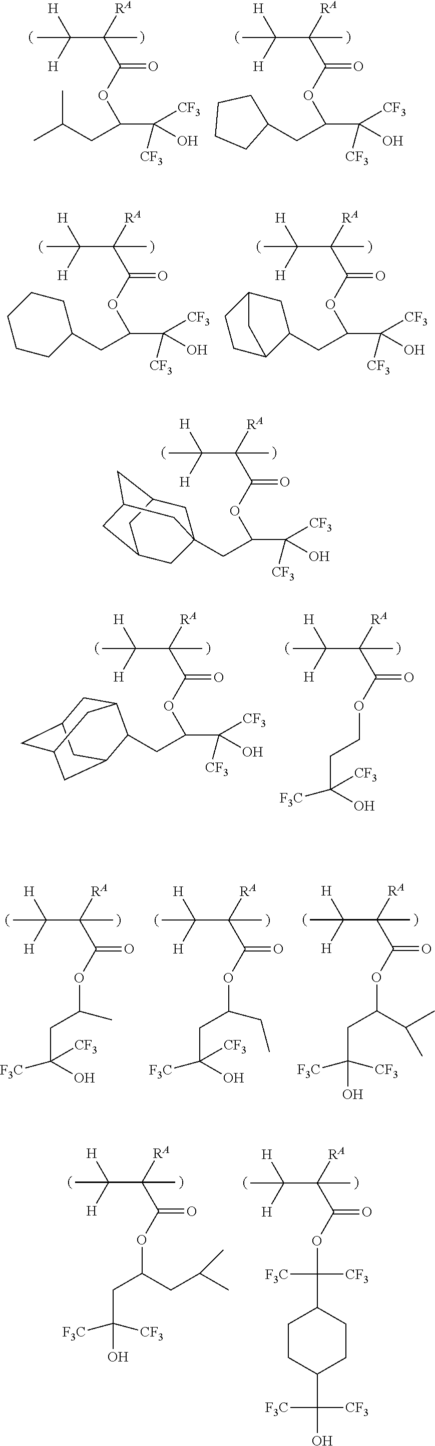

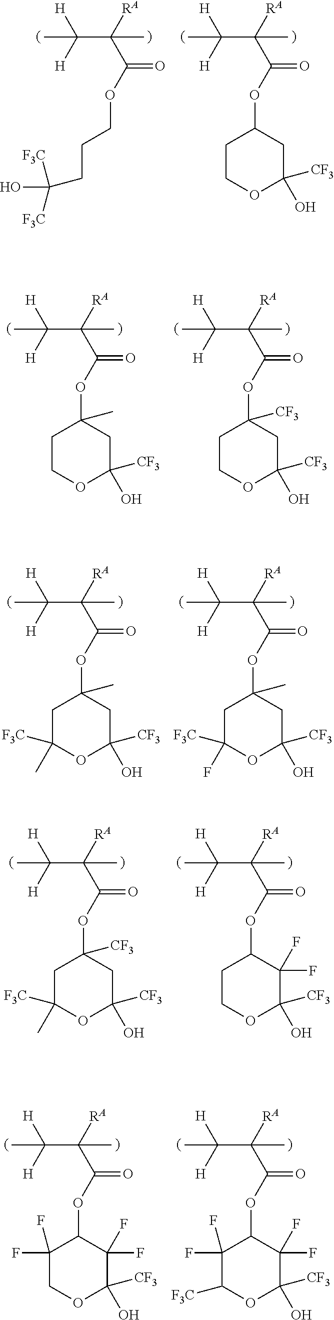

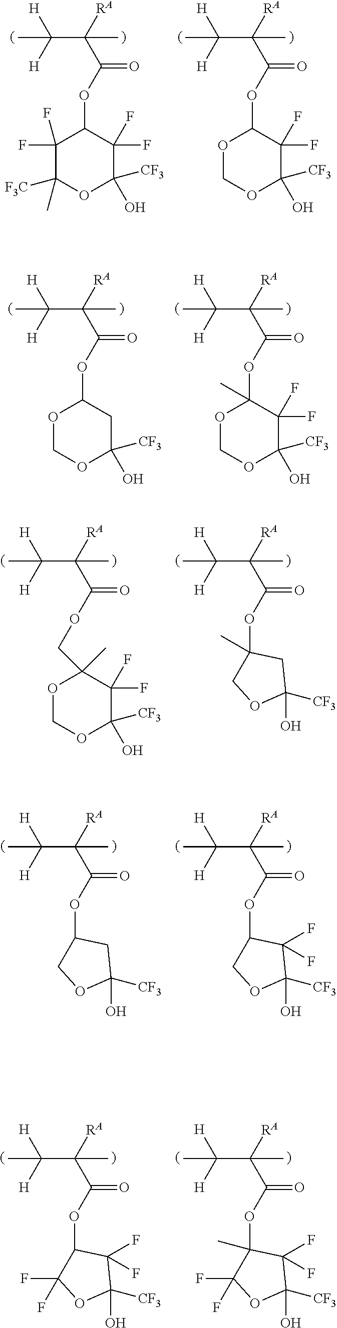

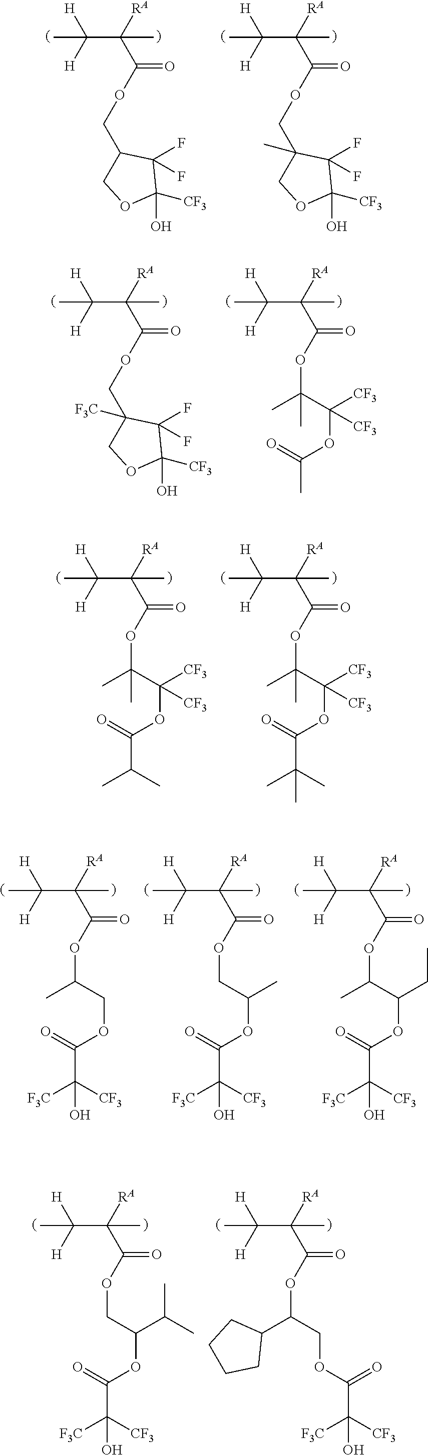

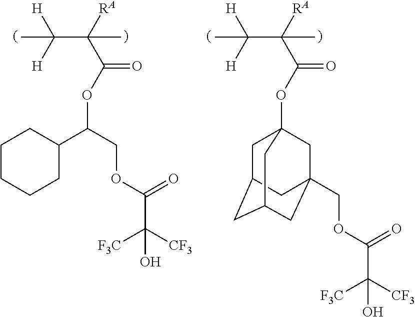

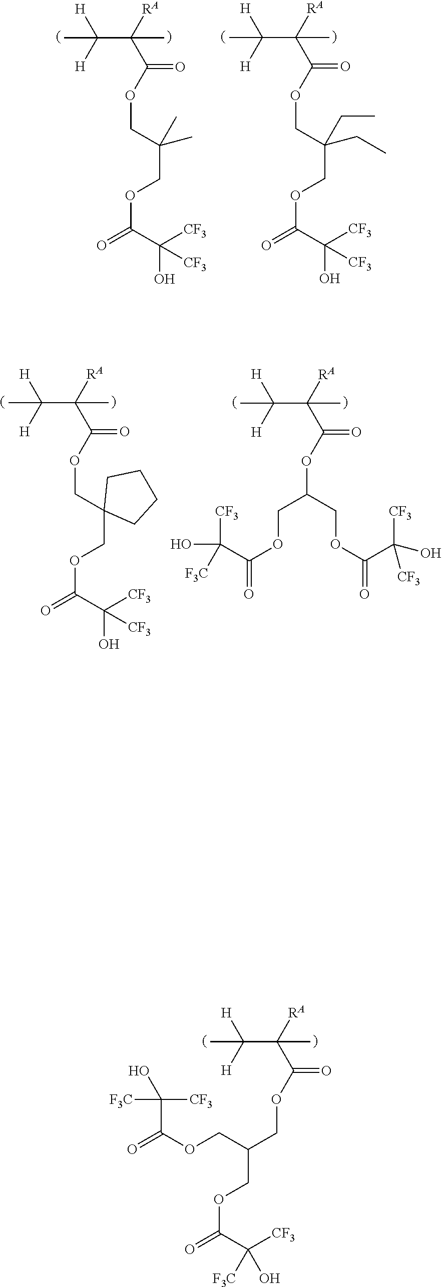

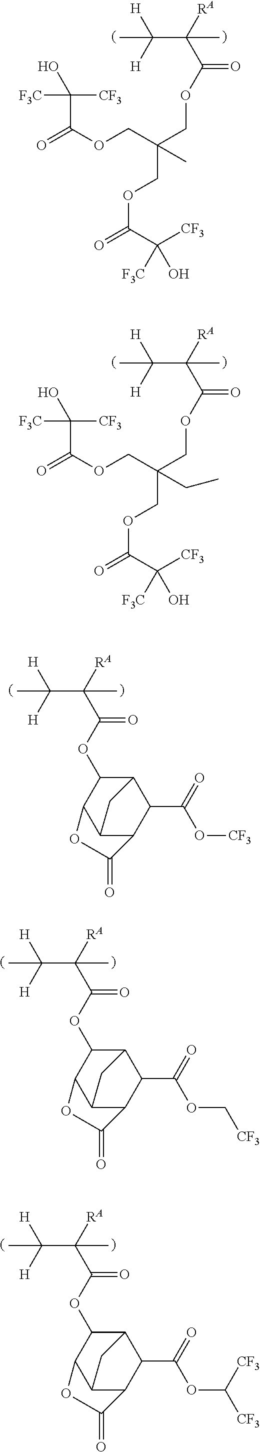

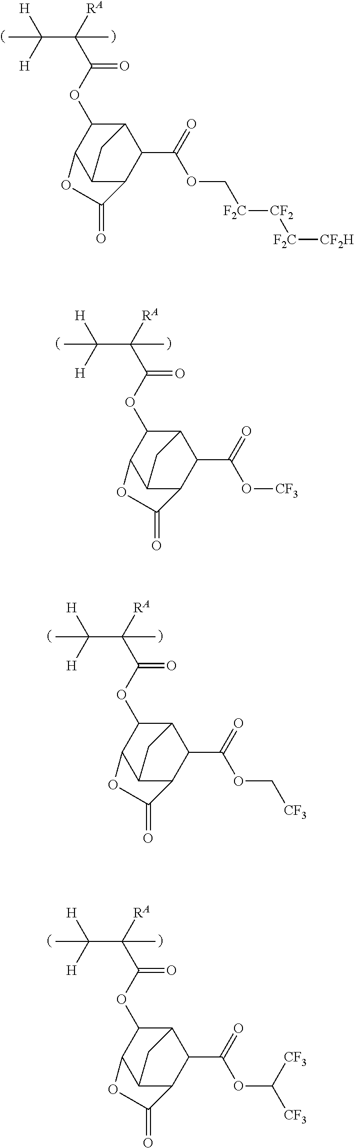

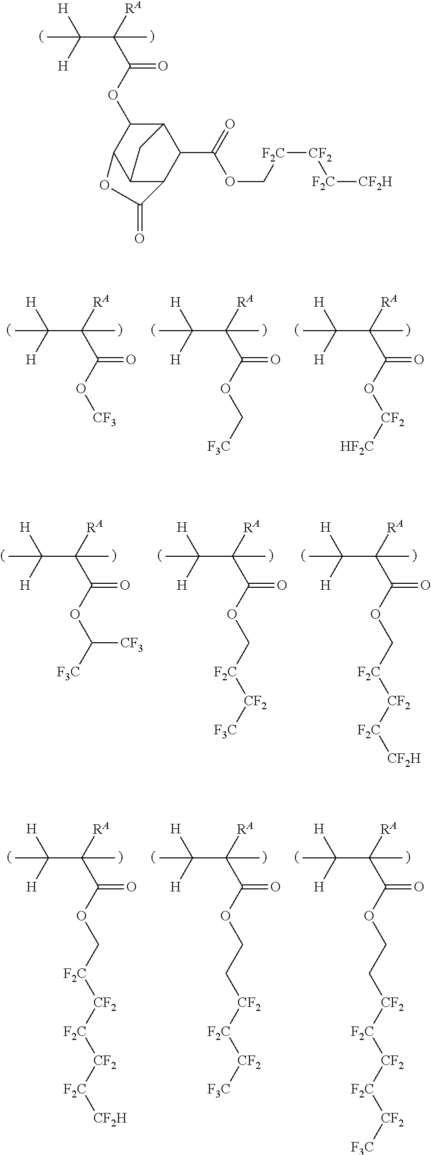

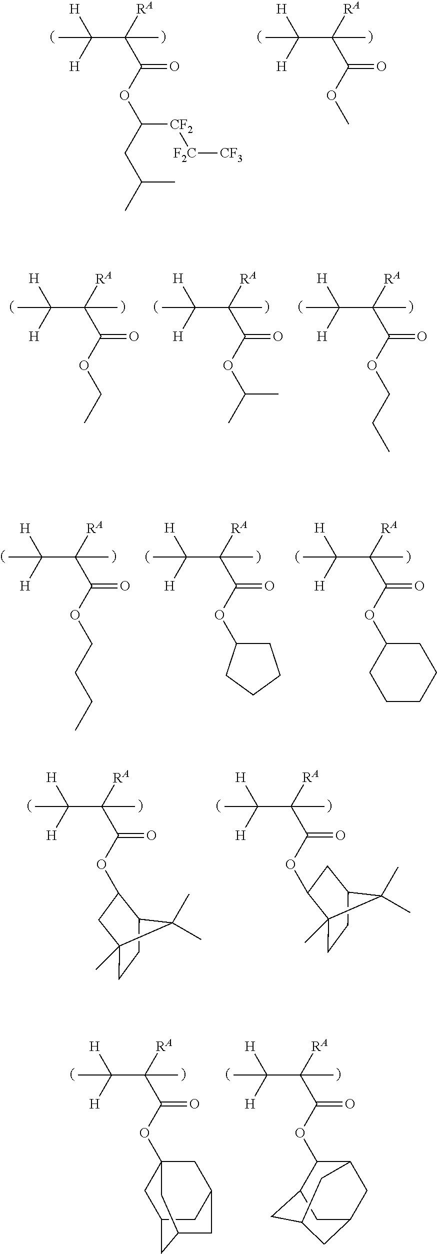

In the carboxy group-containing polymer, the carboxy group-containing recurring unit and another recurring unit are preferably present in a content ratio (molar ratio) of carboxy group-containing recurring unit: another recurring unit=10:90 to 90:10, more preferably 15:85 to 85:15, and still more preferably 20:80 to 80:20.

The carboxy group-containing polymer preferably has a weight average molecular weight (Mw) of 1000 to 500000, and more preferably 3000 to 100000. In the invention, Mw represents a value measured by gel permeation chromatography (GPC) versus polystyrene standards using tetrahydrofuran (THF) as a solvent.

If the carboxy group-containing polymer has a wide molecular weight distribution or dispersity (Mw/Mn), which indicates the presence of lower and higher molecular weight polymer fractions, there is a possibility that foreign matter is left on the pattern or the pattern profile is degraded after exposure. The influences of Mw and Mw/Mn become stronger as the pattern rule becomes finer. Therefore, the carboxy group-containing polymer should preferably have a narrow dispersity (Mw/Mn) of 1.0 to 2.0 in order to provide a resist composition suitable for micropatterning to a small feature size.

Examples of the method of synthesizing the carboxy group-containing polymer include a method in which monomers corresponding to the foregoing recurring units are dissolved in an organic solvent, a radical polymerization initiator is added thereto, and the resulting mixture is heated for polymerization.

Examples of the organic solvent used in the polymerization reaction include toluene, benzene, THF, diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of such an initiator added is preferably 0.01 to 25 mol % per total amount of monomers to be polymerized. The reaction temperature is preferably 50 to 150° C., and more preferably 60 to 100° C. The reaction time is preferably 2 to 24 hours, and more preferably 2 to 12 hours from the viewpoint of production efficiency.

The polymerization initiator may be added to the monomer solution before supply to a reaction vessel, or an initiator solution may be prepared separately from the monomer solution and each solution may be supplied to a reaction vessel independently. Radicals generated from the initiator during waiting time may promote a polymerization reaction to generate an ultrahigh polymer. Therefore, from the viewpoint of quality control, each of the monomer solution and the initiator solution is preferably prepared and added dropwise independently. The acid labile group introduced into the monomer may be used as it is, or may be protected or partially protected after polymerization. Further, a known chain transfer agent such as dodecyl mercaptan or 2-mercaptoethanol may be used in combination for adjusting the molecular weight. In this case, the amount of such a chain transfer agent added is preferably 0.01 to 20 mol % per total amount of monomers to be polymerized.

The amount of each monomer in the monomer solution is to be appropriately set, for example, so as to achieve the foregoing preferred content ratio of the recurring unit.

In the resist composition, the hypervalent iodine compound and the carboxy group-containing polymer are preferably present in a content ratio such that the molar ratio of the hypervalent iodine compound to the carboxylic acid-containing recurring unit in the polymer is 10:90 to 90:10, more preferably 20:80 to 80:20, and still more preferably 30:70 to 70:30. The hypervalent iodine compound may be used alone or in admixture of two or more having different composition ratios and different values of Mw and/or Mw/Mn. The carboxy group-containing polymer may be used alone or in admixture of two or more having different composition ratios and different values of Mw and/or Mw/Mn.

### Solvent

The resist composition contains a solvent. The solvent is not particularly limited as long as the hypervalent iodine compound, the carboxy group-containing polymer, and other components described below are dissolvable therein and a film can be formed from the resulting solution. The solvent is preferably an organic solvent, and examples of the organic solvent include ketones such as cyclohexanone, methyl-2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids such as formic acid, acetic acid, and propionic acid, lactones such as γ-butyrolactone, and mixtures thereof.

In the resist composition, the solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent.

### Other Components

The resist composition may further contain a surfactant. The surfactant is preferably a fluorine-based and/or silicon-based surfactant. Exemplary surfactants are described, for example, in US 2008/0248425, paragraph [0276]. Also useful are surfactants other than the fluorine-based and/or silicon-based surfactants, as described, for example, in US 2008/0248425, paragraph [0280].

When used, the surfactant is preferably present in an amount of 0.0001 to 2% by weight based on the overall solids. The surfactant may be used alone or in admixture.

The resist composition may further contain a radical scavenger. When added, the radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol.

When used, the radical scavenger is preferably present in an amount of 0.01 to 10% by weight based on the overall solids. The radical scavenger may be used alone or in admixture.

As described above, the resist composition contains the hypervalent iodine compound and the carboxy group-containing polymer as main components, but not a polymer containing an acid labile group and a photoacid generator as used in conventional chemically amplified resist compositions. Nevertheless, this resist composition works such that the region thereof exposed to EB or EUV turns soluble in the developer to form a positive tone pattern. Although its mechanism is not well understood, the following mechanism is presumed.

The hypervalent iodine compound is a three-coordinate compound having bonded thereto an aryl group and two carboxylate ligands as represented by the formula (1). When such a three-coordinate iodine compound is mixed with a carboxylic acid, replacement of carboxylate ligands takes place as equilibration reaction. If the original carboxylate ligands are removed by any suitable means, a hypervalent iodine compound having new ligands is created. For example, if iodobenzene diacetate which is relatively readily available as the hypervalent iodine compound is mixed with a carboxylic acid having a high molecular weight, and the resulting low-boiling acetic acid is removed, then ligand exchange is completed. Here, when the carboxylic acid is a polymer, the polymers are crosslinked by the hypervalent iodine compound to form a high molecular weight hypervalent iodine compound.

The polymers crosslinked by the hypervalent iodine compound are generated during film formation. This is because even if synthesized in advance, such crosslinked polymers are insoluble in most organic solvents, so that it is impossible to prepare their solution. This is presumed to be because the hypervalent iodine compound, which is originally low in solvent solubility due to the large polarization, further deteriorates in solubility by using a carboxylic acid-containing polymer that is a high molecular weight compound as a ligand. Therefore, it is desirable that the original low-molecular-weight carboxylic acid is removed during film formation and a subsequent bake step to complete a ligand exchange reaction and form a resist film in the step.

The resist film obtained from the inventive resist composition contains polymers crosslinked by the hypervalent iodine compound that are generated during film formation, and thus has extremely low organic solvent solubility. However, the iodine compound is decomposed with light to form a monovalent iodine compound, and at the same time, the crosslinking between the polymers is released to reduce the molecular weight. It is presumed that as a result, the exposed region becomes soluble in a developer which is an organic solvent and functions in positive tone.

From the foregoing presumption, the inventive resist composition is a non-chemically amplified resist composition, and does not need a polymer containing an acid labile group and a photoacid generator as used in conventional chemically amplified resist compositions. Therefore, a small size pattern can be resolved without an adverse effect (for example, image blur) due to acid diffusion.

The inventive resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, since the inventive resist composition does not use metal elements, it is advantageous in defectiveness over the metal resist and eliminates the problem of solvent solubility. Using the inventive resist composition, a positive tone pattern is formed without development or through organic solvent development. In the step of forming contact holes, for example, the reversal processing step as conducted in negative tone development is unnecessary. From these aspects, the inventive resist composition is regarded more useful than the metal resist composition.

JP-A 2015-180928 and JP-A 2018-95853 describe a resist composition comprising a hypervalent iodine compound as an additive and a resist composition comprising a base polymer having a hypervalent iodine compound incorporated in its framework. It is described in these patent documents that these resist compositions are successful only in improving line edge roughness. They refer nowhere to a possibility of photo-decomposition of the hypervalent iodine compound and an ability to function as a non-chemically amplified resist material. Further, according to the description regarding the compounding amount and specific examples, the hypervalent iodine compound is not a main component in these resist compositions. It is then believed that a material capable of reducing shot noise during the EUV lithography and forming a small size pattern as the non-chemically amplified material is not conceivable from these patent documents. That is, the present invention provides a definitely novel resist composition and pattern forming process.

### Pattern Forming Process

When the resist composition is used in the fabrication of various integrated circuits, any well-known lithography techniques are applicable. For example, the invention provides a pattern forming process comprising the steps of applying the resist composition onto a substrate to form a resist film thereon, exposing the resist film to high-energy radiation, and optionally developing the exposed resist film in a developer.

First, the resist composition is applied onto a substrate for integrated circuit fabrication (e.g., Si, SiO₂, SiN, SiON, TiN, WSi, BPSG, SOG, or organic antireflective coating) or a substrate for mask circuit fabrication (e.g., Cr, CrO, CrON, MoSi₂, or SiO₂) by any suitable technique such as spin coating, roll coating, flow coating, dip coating, spray coating, or doctor coating. The coating is prebaked on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm.

Next the resist film is exposed to high-energy radiation. The radiation is selected from among UV, deep UV, EB, EUV, X-ray, soft X-ray, excimer laser radiation, γ-ray, and synchrotron radiation. On use of UV, deep UV, EUV, X-ray, soft X-ray, excimer laser radiation, T-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 2,000 μC/cm², more preferably about 0.5 to 1,500 μC/cm². The resist composition is best suited in micropatterning using EB or EUV as the high-energy radiation.

If necessary, the resist film is post-exposure baked (PEB). Preferably PEB is performed on a hot plate or in an oven at 30 to 150° C. for 10 seconds to 30 minutes, more preferably at 60 to 120° C. for 30 seconds to 20 minutes.

After the exposure or PEB, the resist film is developed in a developer to form a pattern, if necessary. In the practice of the invention, the exposed region of the resist film is solubilized through organic solvent development to form a positive tone pattern. The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, n-butanol, n-pentanol, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, diacetone alcohol, and 4-methyl-2-pentanol. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Synthesis Examples, Examples, and Comparative Examples of the invention are given below by way of illustration and not by way of limitation.

### [1] Synthesis of Polymer

The following monomers were used for synthesis of polymers.

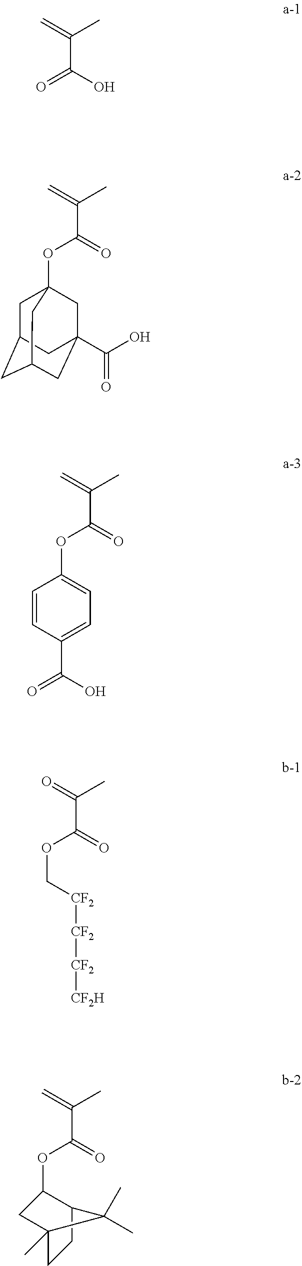

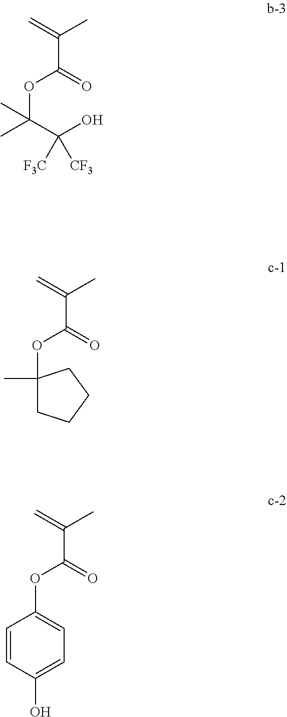 [SMILES: C=C(C)C(=O)OC(C)(C)C(O)(C(F)(F)F)C(F)(F)F ; C=C(C)C(=O)OC1(C)CCCC1 ; C=C(C)C(=O)Oc1ccc(O)cc1]

### Synthesis Example 1 Synthesis of Polymer P-1

In a nitrogen atmosphere, a monomer a-1 (56 g), a monomer b-1 (105 g), V-601 (manufactured by FUJIFILM Wako Pure Chemical Corporation) (5.4 g), and MEK (180 g) were put into a flask to prepare a monomer-polymerization initiator solution. In another flask under a nitrogen atmosphere, 55 g of MEK was put and heated to 80° C. while stirred, and then the monomer-polymerization initiator solution was added dropwise over 4 hours. After completion of the dropwise addition, stir of the polymerization liquid was continued for 2 hours while the liquid temperature was maintained at 80° C., and then the polymerization liquid was cooled to room temperature. The obtained polymerization liquid was added dropwise to 4000 g of vigorously stirred hexane, and the precipitated polymer was separated by filtration. The obtained polymer was washed twice with hexane (1200 g), and then vacuum-dried at 50° C. for 20 hours to obtain a polymer P-1 in the form of a white powder (yield: 155 g, yield rate: 96%). The polymer P-1 had a value of Mw of 7700, and a value of Mw/Mn of 1.82. The value of Mw was measured by GPC versus polystyrene standards using THF as a solvent.

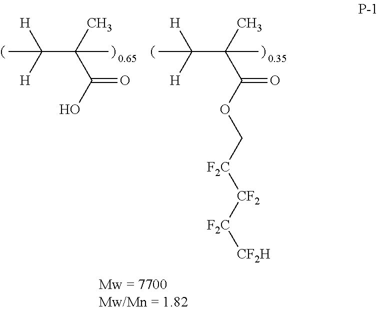

### Synthesis Examples 2 to 12 Synthesis of Polymer P-2 to P-12

Polymers shown in Table 1 was synthesized in the same manner as in Synthesis Example 1 except that the kind and the compounding ratio of each monomer were changed.

TABLE 1

| | | Introduction | | Introduction | | |
|---|---|---|---|---|---|---|
| | Unit | ratio | Unit | ratio | | |
| Polymer | 1 | (mol %) | 2 | (mol %) | Mw | Mw/Mn |
| P-1 | a-1 | 65 | b-1 | 35 | 7,700 | 1.82 |
| P-2 | a-1 | 50 | b-2 | 50 | 8,400 | 1.84 |
| P-3 | a-1 | 60 | b-3 | 40 | 8,100 | 1.79 |
| P-4 | a-2 | 65 | b-1 | 35 | 7,900 | 1.79 |
| P-5 | a-2 | 50 | b-2 | 50 | 8,300 | 1.83 |
| P-6 | a-2 | 60 | b-3 | 40 | 8,200 | 1.82 |
| P-7 | a-3 | 65 | b-1 | 35 | 8,000 | 1.80 |
| P-8 | a-3 | 50 | b-2 | 50 | 8,600 | 1.84 |
| P-9 | a-3 | 60 | b-3 | 40 | 7,900 | 1.81 |
| P-10 | c-1 | 60 | c-2 | 40 | 9,800 | 1.82 |
| P-11 | a-1 | 70 | b-1 | 30 | 8,000 | 1.84 |
| P-12 | a-1 | 80 | b-1 | 20 | 7,900 | 1.82 |

### [2] Preparation of Resist Composition

### Examples 1-1 to 1-15 and Comparative Examples 1-1 to 1-2

Resist compositions (R-01 to R-15) were prepared by dissolving a hypervalent iodine compound and a polymer in a solvent containing 0.01% by weight of a surfactant (PF-636, manufactured by OMNOVA Solutions Inc.) in accordance with the recipe shown in Table 2, and filtering the solution through a Teflon (registered trademark) filter having a pore size of 0.2 μm. Separately, comparative resist compositions (CR-01 to CR-02) were prepared by dissolving a polymer, a photoacid generator, and a sensitivity modifier in a solvent containing 0.01% by weight of a surfactant (PF-636, manufactured by OMNOVA Solutions Inc.) in accordance with the recipe shown in Table 3, and filtering the solution through a Teflon (registered trademark) filter having a pore size of 0.2 μm.

TABLE 2

| | | | Hypervalent | | | |
|---|---|---|---|---|---|---|
| | | | iodine | | | |
| | | Resist | compound | Polymer | Solvent 1 | Solvent 2 |
| | | composition | (pbw) | (pbw) | (pbw) | (pbw) |
| Example | 1-1 | R-01 | I-1 (10) | P-1 (15) | PGMEA (800) | AcOH (200) |
| | 1-2 | R-02 | I-2 (13) | P-1 (15) | PGMEA (800) | AcOH (200) |
| | 1-3 | R-03 | I-3 (11) | P-1 (15) | PGMEA (800) | AcOH (200) |
| | 1-4 | R-04 | I-1 (10) | P-2 (18) | PGMEA (800) | AcOH (200) |
| | 1-5 | R-05 | I-1 (10) | P-3 (17) | PGMEA (800) | AcOH (200) |
| | 1-6 | R-06 | I-1 (10) | P-4 (26) | PGMEA (800) | AcOH (200) |
| | 1-7 | R-07 | I-1 (10) | P-5 (29) | PGMEA (800) | AcOH (200) |
| | 1-8 | R-08 | I-1 (10) | P-6 (28) | PGMEA (800) | AcOH (200) |
| | 1-9 | R-09 | I-1 (10) | P-7 (19) | PGMEA (800) | AcOH (200) |
| | 1-10 | R-10 | I-1 (10) | P-8 (22) | PGMEA (800) | AcOH (200) |
| | 1-11 | R-11 | I-1 (10) | P-9 (21) | PGMEA (800) | AcOH (200) |
| | 1-12 | R-12 | I-1 (9) | P-11 (15) | HBM (800) | AcOH (200) |
| | 1-13 | R-13 | I-1 (8) | P-12 (15) | HBM (800) | PA (200) |
| | 1-14 | R-14 | I-1 (10) | P-1 (15) | HBM (800) | PA (200) |
| | 1-15 | R-15 | I-1 (10) | P-1 (15) | HBM (1000) | — |

TABLE 3

| | | | | Photoacid | Sensitivity | | |
|---|---|---|---|---|---|---|---|
| | | Resist | Polymer | generator | modifier | Solvent 1 | Solvent 2 |
| | | composition | (pbw) | (pbw) | (pbw) | (pbw) | (pbw) |
| Comparative | 1-1 | CR-01 | P-1 | PAG-1 | Q-1 | PGMEA | GBL |
| Example | | | (80) | (19) | (6) | (1890) | (210) |
| | 1-2 | CR-02 | P-1 | PAG-1 | I-1 | PGMEA | GBL |
| | | | (80) | (19) | (5) | (1890) | (210) |

In Tables 2 and 3, the hypervalent iodine compound (I-1 to I-3), the photoacid generator PAG-1, the sensitivity modifier Q-1, and the solvent are identified below.

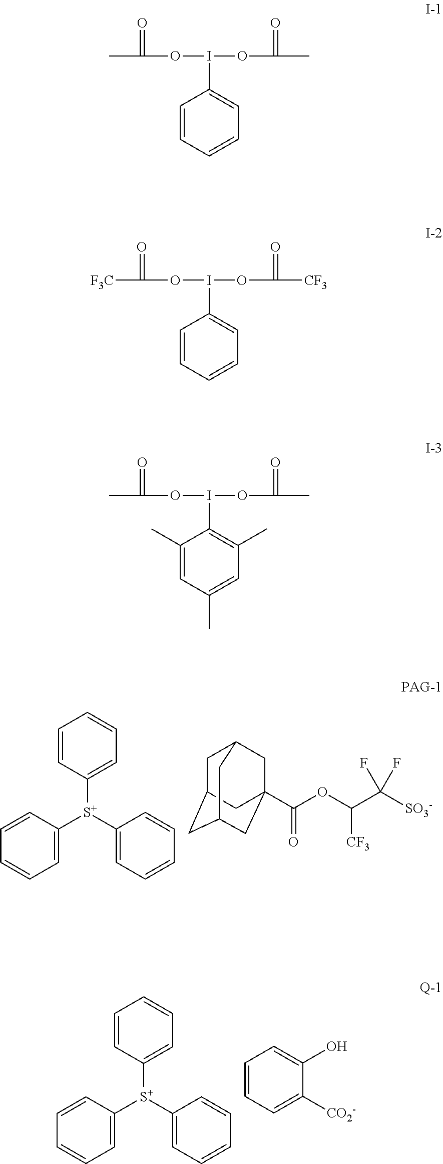

### Solvent:

PGMEA (propylene glycol monomethyl ether acetate)
AcOH (acetic acid)
GBL (γ-butyrolactone)
HBM (methyl 2-hydroxyisobutyrate)
PA (propionic acid)

### [3] EUV Lithography Test (Line-and-Space)

### Examples 2-1 to 2-15 and Comparative Examples 2-1 to 2-2

Each of the resist compositions (R-01 to R-15, CR-01 to CR-02) was spin coated on a silicon substrate having a 20-nm coating of silicon-containing spin-on hard mask SHB-A940 (Shin-Etsu Chemical Co., Ltd., silicon content 43 wt %) and prebaked (PAB) on a hotplate at the temperature shown in Table 4 for 60 seconds to form a resist film of 40 nm thick. Using an EUV scanner NXE3400 (ASML, NA 0.33, a 0.9, 900 dipole illumination), the resist film was exposed to EUV through a mask bearing a 36-nm 1:1 line-and-space (LS) pattern. The resist film was baked (PEB) on a hotplate at the temperature shown in Table 4 for 60 seconds and developed in the developer shown in Table 4 for 30 seconds to form a LS pattern having a space width of 18 nm and a pitch of 36 nm.

The obtained resist pattern was evaluated as follows. Table 4 shows the results.

### Evaluation of Sensitivity

The LS pattern was observed under CD-SEM (CG-6300, Hitachi High-Tech Corporation), and the optimum dose (Eop, mJ/cm²) which provided an LS pattern with a space width of 18 nm and a pitch of 36 nm was determined and reported as sensitivity.

### Evaluation of LWR

An LS pattern was formed by exposure in the optimum dose (Eop). The space width was measured under CD-SEM (CG-6300, Hitachi High-Tech Corporation) at longitudinally spaced apart 10 points, from which a 3-fold value (3a) of the standard deviation (σ) was determined and reported as LWR. A smaller value indicates a pattern having a lower roughness and more uniform space width.

### Evaluation of Maximum Resolution

An LS pattern was formed while increasing the exposure dose little by little from the optimum dose (Eop). The line width (nm) which could be resolved was determined under CD-SEM (CG-6300, Hitachi High-Tech Corporation) and reported as maximum resolution (nm). A smaller value indicates a pattern having a better maximum resolution and smaller feature size.

TABLE 4

| | | | | | | | Maximum |
|---|---|---|---|---|---|---|---|
| | | Resist | PAB/PEB | | Eop | LWR | resolution |
| | | composition | (° C.) | Developer | (mJ/cm²) | (nm) | (nm) |
| Example | 2-1 | R-01 | 130/90 | nBA | 39 | 3.6 | 14 |
| | 2-2 | R-02 | 130/90 | nBA | 39 | 3.6 | 14 |
| | 2-3 | R-03 | 130/90 | nBA | 36 | 3.4 | 16 |
| | 2-4 | R-04 | 130/90 | nBA | 42 | 3.8 | 13 |
| | 2-5 | R-05 | 130/90 | nBA | 44 | 3.5 | 13 |
| | 2-6 | R-06 | 130/90 | nBA | 45 | 3.7 | 16 |
| | 2-7 | R-07 | 130/90 | nBA | 44 | 3.8 | 16 |
| | 2-8 | R-08 | 130/90 | nBA | 45 | 3.6 | 16 |
| | 2-9 | R-09 | 130/90 | nBA | 40 | 3.5 | 16 |
| | 2-10 | R-10 | 130/90 | nBA | 42 | 3.7 | 14 |
| | 2-11 | R-11 | 130/90 | nBA | 42 | 3.4 | 16 |
| | 2-12 | R-12 | 130/90 | nBA | 38 | 3.6 | 16 |
| | 2-13 | R-13 | 130/90 | nBA | 37 | 3.5 | 16 |
| | 2-14 | R-14 | 130/90 | nBA | 40 | 3.6 | 14 |
| | 2-15 | R-15 | 130/90 | nBA | 40 | 3.6 | 14 |
| Comparative | 2-1 | RC-01 | 105/90 | TMAH | 80 | 4.5 | 18 |
| Example | 2-2 | RC-02 | 105/90 | TMAH | 85 | 4.8 | 18 |

### Developer:

nBA (butyl acetate)
TMAH (2.38 wt % aqueous tetramethylammonium hydroxide solution)

It is evident from Table 4 that the resist compositions within the scope of the invention form LS patterns having satisfactory sensitivity, LWR, and resolution when processed by the EUV lithography.

### [4] EUV Lithography Test (Contact Hole Pattern)

### Examples 3-1 to 3-15 and Comparative Examples 3-1 to 3-2

Each of the resist compositions (R-01 to R-15, CR-01 to CR-02) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 5 for 60 seconds to form a resist film of 50 nm thick. Using an EUV scanner NXE3400 (ASML, NA 0.33, a 0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 5 for 60 seconds and developed in the developer shown in Table 5 for 30 seconds to form a hole pattern having a size of 32 nm.

The obtained resist pattern was evaluated as follows. Table 5 shows the results.

### Evaluation of Sensitivity

The contact hole pattern was observed under CD-SEM (CG-6300, Hitachi High-Tech Corporation), and the optimum dose (Eop, mJ/cm²) which provided a hole pattern with a size of 22 nm was determined and reported as sensitivity.

### Evaluation of CDU

The size of 50 holes which were printed at Eop was measured, from which a 3-fold value (3σ) of the standard deviation (σ) was computed and reported as CDU. A smaller value of CDU indicates a hole pattern with more uniform hole diameter.

### Evaluation of Maximum Resolution

A hole pattern was formed while reducing the exposure dose little by little from the optimum dose (Eop). The hole diameter (nm) which could be resolved was determined under CD-SEM (CG-6300, Hitachi High-Tech Corporation) and reported as maximum resolution. A smaller value indicates a pattern having a better maximum resolution and smaller hole diameter.

TABLE 5

| | | | | | | | Maximum |
|---|---|---|---|---|---|---|---|
| | | Resist | PAB/PEB | | Eop | LWR | resolution |
| | | composition | (° C.) | Developer | (mJ/cm²) | (nm) | (nm) |
| Example | 3-1 | R-01 | 130/90 | nBA | 24 | 2.7 | 26 |
| | 3-2 | R-02 | 130/90 | nBA | 26 | 2.7 | 26 |
| | 3-3 | R-03 | 130/90 | nBA | 26 | 2.8 | 28 |
| | 3-4 | R-04 | 130/90 | nBA | 28 | 2.8 | 24 |
| | 3-5 | R-05 | 130/90 | nBA | 28 | 2.7 | 26 |
| | 3-6 | R-06 | 130/90 | nBA | 26 | 2.9 | 28 |
| | 3-7 | R-07 | 130/90 | nBA | 25 | 2.9 | 26 |
| | 3-8 | R-08 | 130/90 | nBA | 27 | 2.7 | 26 |
| | 3-9 | R-09 | 130/90 | nBA | 28 | 2.6 | 28 |
| | 3-10 | R-10 | 130/90 | nBA | 29 | 2.8 | 28 |
| | 3-11 | R-11 | 130/90 | nBA | 28 | 2.6 | 26 |
| | 3-12 | R-12 | 130/90 | nBA | 23 | 2.7 | 28 |
| | 3-13 | R-13 | 130/90 | nBA | 23 | 2.6 | 28 |
| | 3-14 | R-14 | 130/90 | nBA | 25 | 2.8 | 26 |
| | 3-15 | R-15 | 130/90 | nBA | 25 | 2.6 | 25 |
| Comparative | 3-1 | RC-01 | 105/90 | TMAH | 42 | 3.8 | 32 |
| Example | 3-2 | RC-02 | 105/90 | TMAH | 40 | 4.0 | 32 |

It is evident from Table 5 that the resist compositions within the scope of the invention form contact hole patterns having satisfactory sensitivity, CDU, and resolution when processed by the EUV lithography.

Japanese Patent Application No. 2022-208497 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a hypervalent iodine compound having the formula (1), a carboxy group-containing polymer, and a solvent: 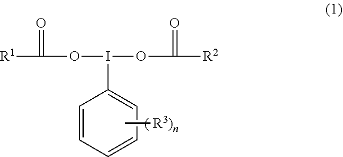
wherein n is an integer of 0 to 5,
R¹ and R² are each independently halogen or a C₁-C₁₀ hydrocarbyl group which may contain a heteroatom, R¹ and R² may bond together to form a ring with the carbon atoms to which they are attached and the intervenient atoms, and
R³ is halogen or a C₁-C₄₀ hydrocarbyl group which may contain a heteroatom.

2. The resist composition of claim 1 wherein the carboxy group-containing polymer comprises a recurring unit having the formula (2): 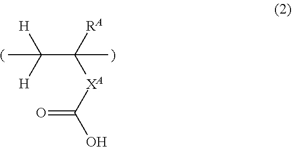
wherein R^{A} is a hydrogen atom, fluorine atom, methyl group, or trifluoromethyl group,
X^{A} is a single bond, phenylene group, naphthylene group, or *—C(═O)—O—X^{A1}— wherein X^{A1} is a C₁-C₁₀ saturated hydrocarbylene group, phenylene group, or naphthylene group, the C₁-C₁₀ saturated hydrocarbylene group may contain a hydroxy group, ether bond, ester bond, or lactone ring, and * designates a valence bond to a carbon atom in a main chain.

3. A pattern forming process comprising the steps of applying the resist composition of claim 1 onto a substrate to form a resist film thereon, exposing the resist film to an electron beam or an extreme ultraviolet radiation, and developing the exposed resist film in a developer.

4. The pattern forming process of claim 3 wherein the developer is an organic solvent.
